(19) United States
(12) Patent Application Publication
(10) Pub. No.: US 2024/0414928 A1
(43) Pub. Date: Dec. 12, 2024

(54) PEROVSKITE PHOTOACTIVE COMPOSITE LAYER, PREPARATION METHOD THEREOF, AND PEROVSKITE SOLAR CELL COMPRISING THE SAME

(71) Applicant: Gwangju Institute Of Science And Technology, Gwangju (KR)

(72) Inventors: Kwang Hee LEE, Gwangju (KR); Ju Hyeon KIM, Gwangju (KR)

(21) Appl. No.: 18/437,231

(22) Filed: Feb. 8, 2024

(30) Foreign Application Priority Data
Jun. 7, 2023 (KR) 10-2023-0072879

(51) Int. Cl. H10K 30/50; H10K 30/86; H10K 85/50

(52) U.S. Cl. CPC H10K 30/50; H10K 30/86; H10K 85/50

(57) ABSTRACT

A perovskite photoactive composite layer, a preparation method thereof, and a perovskite solar cell comprising the same are provided. The perovskite photoactive composite layer can induce smooth charge transport when applied to a solar cell by means of a two-dimensional perovskite photoactive layer grown by recrystallization in the vertical direction, and can passivate surface defects in two-dimensional perovskites and prevent the release of halogen atoms through effective passivation by means of a passivation layer consisting of an organic monomolecular compound containing zwitterions, thereby improving the photostability of the solar cell.

### CROSS-REFERENCE TO RELATED PATENT APPLICATION

This application claims the benefit of Korean Patent Application No. 10-2023-0072879, filed on Jun. 7, 2023, in the Korean Intellectual Property Office, the disclosure of which is incorporated herein in its entirety by reference.

### BACKGROUND OF THE INVENTIVE CONCEPT

### 1. Field of the Inventive Concept

The present inventive concept relates to a perovskite photoactive composite layer for improving the photostability and efficiency of solar cells, and more particularly, to a perovskite photoactive composite layer, a preparation method thereof, and a perovskite solar cell comprising the same, which can induce vertical crystal orientations of two-dimensional perovskites and can effectively passivate the defects in the perovskite photoactive composite layer.

### 2. Description of the Related Art

Perovskite materials are being researched for application in various optoelectronic devices, including solar cells, due to their excellent electrical and optical properties, as well as their processability in solutions, which offer the significant advantage of low production costs relative to high efficiency.

Solar cells incorporating such perovskite materials are broadly composed of an anode, a cathode, n-type and p-type charge transport layers, and a perovskite photoactive layer. According to the National Renewable Energy Laboratory (NREL) in the United States, it has been reported that perovskite-based solar cells currently exhibit unit cell efficiency (26.1%), which is comparable to commercialized first-generation silicon-based solar cells (26.1%). This pertains to the efficiency of solar cells based on three-dimensional (3D) perovskite materials. Solar cells based on two-dimensional (2D) perovskites still exhibit low power conversion efficiency.

Nevertheless, as in prior art 1 (Korea Patent No. 10-2347937) and prior art 2 (Korea Patent Application Publication No. 10-2022-0157611) two-dimensional perovskite materials exhibit greater environmental stability along with unique optoelectronic properties, compared to three-dimensional perovskites, and thus have attracted much attention as next-generation solar cell materials with long-term stability and high performance.

However, although vertical electron transfer is required in solar cells, two-dimensional perovskite materials have a thermodynamic preference for horizontal arrangement, and their low-quality surface properties such as surface defects lead to a decrease in the efficiency of solar cells.

Therefore, to enhance the efficiency of solar cells based on two-dimensional perovskite materials, there is a need for the development of two-dimensional perovskite materials with a vertical orientation. Moreover, there is a demand for new technological developments in passivation to minimize the occurrence of defects or the loss of charge transfer that leads to a degradation of the performance of solar cells based on existing two-dimensional perovskite materials.

### SUMMARY OF THE INVENTIVE CONCEPT

The present inventive concept has been made in an effort to solve the above-described problems associated with prior art, and an object of the present inventive concept is to provide a perovskite photoactive composite layer, a preparation method thereof, and a perovskite solar cell comprising the same, which can induce smooth charge transfer through two-dimensional perovskites with a vertical orientation.

Moreover, other objects of the present inventive concept are to provide a perovskite photoactive composite layer, a preparation method thereof, and a perovskite solar cell comprising the same, which can improve the photostability and efficiency through the passivation of surface defects of perovskites.

One aspect of the present inventive concept provides a perovskite photoactive composite layer comprising: a two-dimensional perovskite photoactive layer; and a passivation layer which is in physical contact with the perovskite photoactive layer and consists of an organic monomolecular compound represented by the following Formula 1:

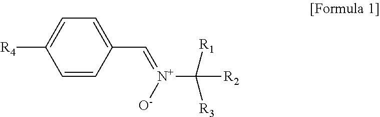

wherein R₁, R₂ and R₃ are each independently hydrogen or C₁-C₃₀ alkyl, and R₄ is hydrogen or an aromatic compound.

In one embodiment, in Formula 1, R₁, R₂, and R₃ may each independently be methyl, and R₄ may be hydrogen.

The perovskite photoactive layer may be grown by recrystallization in the vertical direction.

Another aspect of the present inventive concept is to provide a method of preparing the perovskite photoactive composite layer of claim 1, the method comprising the steps of: preparing a perovskite precursor solution by dissolving a solute containing phenethylammonium iodide (PEAI), methylammonium iodide (MAI), lead iodide (Pbl₂), and lead chloride (PbCl₂) in a first solvent; forming a perovskite precursor thin film by applying the perovskite precursor solution to a substrate; forming a two-dimensional perovskite photoactive layer by subjecting the perovskite precursor thin film to vacuum treatment, followed by thermal annealing; preparing an organic monomolecular compound solution by dissolving an organic monomolecular compound represented by the above Formula 1 in a second solvent; and forming a passivation layer by applying the organic monomolecular compound solution onto the top of the perovskite photoactive layer.

The organic monomolecular compound may be N-tert-butyl-α-phenylnitrone (PBN).

The solute may contain 20 to 25 parts by weight of methylammonium iodide (MAI) and 60 to 65 parts by weight of lead iodide (Pbl₂) with respect to 14 parts by weight of phenethylammonium iodide (PEAI).

The first solvent may comprise at least one selected from the group consisting of dimethylformamide (DMF) and dimethylsulfoxide (DMSO).

In the step of forming the perovskite precursor thin film, the perovskite precursor solution may be applied to the substrate by spin coating.

In the step of forming the perovskite photoactive layer, the perovskite precursor thin film may be subjected to vacuum treatment at −1 to −3 bar for 8 to 10 minutes, followed by thermal annealing at 100 to 110° C. for 5 to 15 minutes.

The second solvent may be isopropyl alcohol (IPA).

In the step of forming the organic monomolecular compound solution, 0.05 to 0.10 parts by weight of N-tert-butyl-α-phenylnitrone (PBN) may be mixed with 100 parts by weight of the second solvent.

Still another aspect of the present inventive concept is to provide a perovskite solar cell comprising: a first electrode; a hole transport layer formed on the first electrode; a perovskite photoactive composite layer formed on the hole transport layer and comprising a two-dimensional perovskite photoactive layer and a passivation layer which is in physical contact with the perovskite photoactive layer and consists of an organic monomolecular compound represented by the above Formula 1; a charge transport layer formed on the perovskite photoactive composite layer; and a second electrode formed on the charge transport layer.

The organic monomolecular compound may contain zwitterions, and the zwitterions may be ionically bound to halogen atoms of the perovskite photoactive layer to inhibit the release of halogen atoms.

In terms of photostability, when the perovskite solar cell is exposed to light and measured by a maximum power point tracking method under a nitrogen atmosphere, the solar cell may retain its performance at 88% of the initial efficiency even after 1,000 hours.

According to the perovskite photoactive composite layer and the preparation method thereof of the present inventive concept, it is possible to form a high-quality two-dimensional perovskite by allowing the perovskite crystals to be aligned in the vertical direction.

Therefore, according to the solar cell comprising the perovskite photoactive composite layer of the present inventive concept, it is possible to improve the power conversion efficiency and photostability by facilitating the charge transport to reduce the recombination loss.

Moreover, according to the perovskite photoactive composite layer, the preparation method thereof, and the perovskite solar cell comprising the same of the present inventive concept, it is possible to prevent the release of halogen atoms by means of the passivation layer consisting of an organic monomolecular compound having zwitterionic properties, and further improve the quality of the perovskite photoactive composite layer by passivating the surface defects present in the material itself.

Furthermore, according to the perovskite photoactive composite layer, the preparation method thereof, and the perovskite solar cell comprising the same of the present inventive concept, it is possible to easily introduce the organic monomolecular compound into the two-dimensional perovskite photoactive layer through a simple solution process.

In addition, according to the perovskite photoactive composite layer and the preparation method thereof of the present inventive concept, it is possible to find their applications in various fields such as optoelectronic devices including photodetectors, light-emitting diodes, thin-film transistors, and photoelectrochemical cells, which employ two-dimensional perovskite materials, in addition to the above-mentioned solar cell applications.

The technical effects of the present inventive concept are not limited to those mentioned above, and other technical effects not mentioned will be clearly understood by those skilled in the art from the description below.

### BRIEF DESCRIPTION OF THE DRAWINGS

The above and other features and advantages of the present inventive concept will become more apparent by describing in detail exemplary embodiments thereof with reference to the attached drawings in which:

FIG. 1 is a flowchart illustrating a method of preparing a perovskite photoactive composite layer according to an embodiment of the present inventive concept;

FIG. 2 is a schematic diagram illustrating the structure of a perovskite solar cell according to an embodiment of the present inventive concept;

FIG. 3 is a diagram illustrating the results of time-of-flight secondary-ion mass spectrometry (TOF-SIMS) of perovskite photoactive composite layers of Example 1 according to an embodiment of the present inventive concept;

FIG. 4 shows graphs illustrating the ultraviolet photoelectron emission spectra of a perovskite photoactive layer of Comparative Example 1 and the perovskite photoactive composite layers of Example 1 according to an embodiment of the present inventive concept, and images representing their energy band structures;

FIG. 5a shows graphs illustrating the results of grazing-incidence wide-angle X-ray scattering analysis of the perovskite photoactive layer of Comparative Example 1 and the perovskite photoactive composite layer of Example 1 according to an embodiment of the present inventive concept.

FIG. 5b shows graphs illustrating the analysis results of the crystal intensity in the vertical plane and horizontal plane of Comparative Example 1 and the perovskite photoactive composite layer of Example 1 according to an embodiment of the present inventive concept.

FIG. 5c shows graphs illustrating the analysis results of the crystal intensity at each angle of Comparative Example 1 and the perovskite photoactive composite layer of Example 1 according to an embodiment of the present inventive concept.

FIG. 6 illustrates the results of analyzing the cross-sections of the perovskite photoactive layer of Comparative Example 1 and the perovskite photoactive composite layers of Example 1 according to an embodiment of the present inventive concept by scanning electron microscopy (SEM);

FIG. 7 shows graphs illustrating the results of measuring the space-charge limited current (SCLC) in the perovskite photoactive layer of Comparative Example 1 and the perovskite photoactive composite layers of Example 1 according to an embodiment of the present inventive concept;

FIG. 8 is a graph illustrating the results of analyzing the density and energy changes depending on the density of trap states in the perovskite photoactive layer of Comparative Example 1 and the perovskite photoactive composite layers of Example 1 according to an embodiment of the present inventive concept;

FIG. 9 shows graphs illustrating the results of measuring the transient absorption and photobleaching for each wavelength region in the perovskite photoactive layer of Comparative Example 1 and the perovskite photoactive composite layers of Example 1 according to an embodiment of the present inventive concept;

FIG. 10 shows graphs illustrating the results of analyzing the photoluminescence and time-correlated single photon counting in the perovskite photoactive layer of Comparative Example 1 and the perovskite photoactive composite layers of Example 1 according to an embodiment of the present inventive concept;

FIG. 11 shows images of the perovskite photoactive layer of Comparative Example 1 and the perovskite photoactive composite layers of Example 1 according to an embodiment of the present inventive concept taken by confocal laser scanning microscopy (CLSM);

FIG. 12 shows a graph illustrating the results of measuring the current density as a function of voltage in a perovskite solar cell of Comparative Example 2 and a perovskite solar cell of Example 2 according to an embodiment of the present inventive concept;

FIG. 13 shows a graph illustrating the power conversion efficiency (PCE) in the perovskite solar cell of Example 2 according to an embodiment of the present inventive concept;

FIG. 14 shows a graph illustrating the changes in efficiency over time in the perovskite solar cell of Comparative Example 2 and the perovskite solar cell of Example 2 according to an embodiment of the present inventive concept;

FIG. 15 shows a graph illustrating the results of measuring the ultraviolet-visible absorption spectra of the control iodine solution and a solution of the organic monomolecular according to an embodiment of the present inventive concept dissolved in the iodine.

FIG. 16 illustrates the results of simulation analysis of the electrostatic potential in the iodine and the organic monomolecular compound of Formula 1 according to an embodiment of the present inventive concept; and

FIG. 17 shows graphs illustrating the results of time-of-flight secondary-ion mass spectrometry (TOF-SIMS) of the perovskite solar cell of Comparative Example 2 and the perovskite solar cell of Example 2 according to an embodiment of the present inventive concept.

### DETAILED DESCRIPTION OF THE INVENTIVE CONCEPT

Hereinafter, embodiments according to the present inventive concept will be described in detail with reference to the accompanying drawings.

While the present inventive concept allows for various modifications and variations, specific embodiments thereof are illustrated by the drawings, which will be described in detail below. However, it is not intended to limit the inventive concept to the particular forms disclosed, but rather the inventive concept includes all modifications, equivalents, and substitutes consistent with the spirit of the inventive concept as defined by the claims.

It will be understood that when an element such as a layer, region, or substrate is referred to as being “on” another element, it can be directly on the other element or intervening elements may also be present.

It will be understood that, although the terms “first”, “second”, etc. may be used herein to describe various elements, components, regions, layers, and/or sections, these elements, components, regions, layers, and/or sections should not be limited by these terms.

### Perovskite Photoactive Composite Layer

One aspect of the present inventive concept provides a perovskite photoactive composite layer comprising: a two-dimensional perovskite photoactive layer; and a passivation layer which is in physical contact with the perovskite photoactive layer and consists of an organic monomolecular compound represented by the following Formula 1:

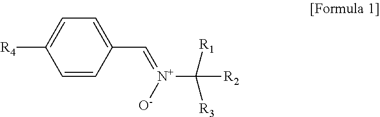

wherein R₁, R₂ and R₃ are each independently hydrogen or C₁-C₃₀ alkyl, and R₄ is hydrogen or an aromatic compound.

In one embodiment, in Formula 1, R₄ may be selected from the group consisting of hydrogen, benzene, naphthalene, and anthracene.

Specifically, the perovskite photoactive composite layer may comprise a perovskite photoactive layer and a passivation layer disposed on the perovskite photoactive layer. That is, according to the present inventive concept, the two-dimensional perovskite photoactive layer may be first formed, and then the resulting perovskite photoactive layer may be post-treated with an organic monomolecular compound.

The perovskite photoactive layer may consist of a perovskite material and may be used as a photoactive layer when applied to a solar cell. The perovskite photoactive layer may be grown by recrystallization in the vertical direction.

In detail, the perovskite photoactive layer may have a two-dimensional structure of A₂′MX₄, where A may be a large organic cation, M may be a metal cation, and X may be a halide anion. That is, the two-dimensional perovskite photoactive layer may be grown by recrystallization in the vertical direction. The perovskite photoactive layer grown by recrystallization in the vertical direction can facilitate the transport of charges in the vertical direction within the solar cell through energy level variations, thereby improving the power conversion efficiency of the solar cell.

The passivation layer may be physically coupled to the two-dimensional perovskite photoactive layer to induce the recrystallization growth of the perovskite photoactive layer in the vertical direction. Moreover, the passivation layer can effectively passivate ionic defects formed on the surface of conventional two-dimensional perovskites, thereby improving the performance and photostability of solar cells comprising the same.

In detail, the passivation layer may consist of an organic monomolecular compound. The organic monomolecular compound may refer to a substance containing both alkyl and aromatic side chains based on a nitrone functional group. In more detail, the organic monomolecular compound may be represented by the above Formula 1, wherein R₁, R₂, and R₃ may each independently be methyl, and R₄ may be hydrogen. That is, the organic monomolecular compound may be N-tert-butyl-α-phenylnitrone (PBN).

As described above, according to the perovskite photoactive composite layer of the present inventive concept comprising a two-dimensional perovskite photoactive layer and a passivation layer physically coupled to the perovskite photoactive layer by post-treating the perovskite photoactive layer with an organic monomolecular compound, it is possible to provide a perovskite photoactive layer with a high-quality two-dimensional perovskite photoactive layer grown by recrystallization in the vertical direction, passivating the surface defects in the perovskite photoactive layer, and inhibit the release of halogen ions.

Therefore, the perovskite photoactive composite layer of the present inventive concept can effectively address the issues of conventional two-dimensional perovskites, where the horizontal crystal orientation is induced, leading to a loss in electricity due to ionic defects.

### Preparation Method of Perovskite Photoactive Composite Layer

Another aspect of the present inventive concept provides a method of preparing the above-described perovskite photoactive composite layer.

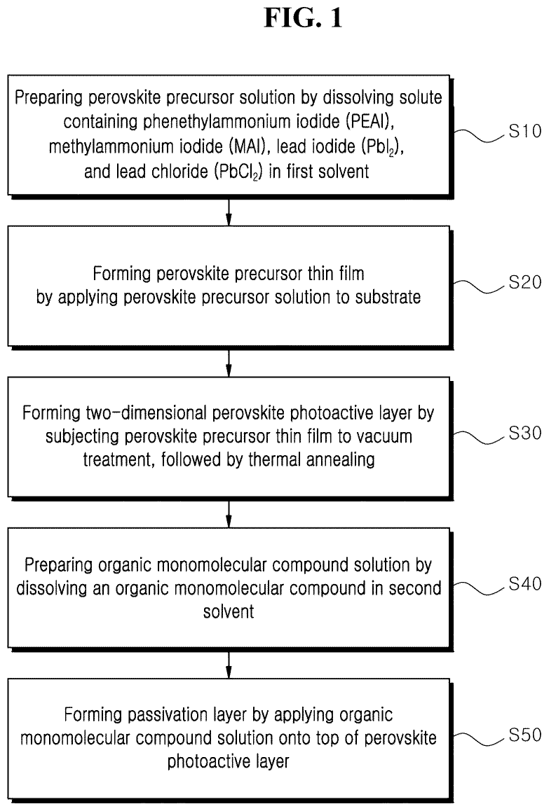

FIG. 1 is a flowchart illustrating a method of preparing a perovskite photoactive composite layer according to an embodiment of the present inventive concept.

Referring to FIG. 1, the method of preparing a perovskite photoactive composite layer may comprise the steps of: preparing a perovskite precursor solution by dissolving a solute containing phenethylammonium iodide (PEAI), methylammonium iodide (MAI), lead iodide (Pbl₂), and lead chloride (PbCl₂) in a first solvent (S10); forming a perovskite precursor thin film by applying the perovskite precursor solution to a substrate (S20); forming a two-dimensional perovskite photoactive layer by subjecting the perovskite precursor thin film to vacuum treatment, followed by thermal annealing (S30); preparing an organic monomolecular compound solution by dissolving an organic monomolecular compound represented by the above Formula 1 in a second solvent (S40); and forming a passivation layer by applying the organic monomolecular compound solution onto the top of the perovskite photoactive layer (S50).

That is, according to the present inventive concept, it is possible to easily form the passivation layer consisting of the organic monomolecular compound on the two-dimensional perovskite photoactive layer through a simple solution process. The use of such a simplified process allows for the formation of a perovskite photoactive composite layer with high optical properties, making it highly applicable for use in large-area devices.

First, a solute containing phenethylammonium iodide (PEAI), methylammonium iodide (MAI), lead iodide (Pbl₂), and lead chloride (PbCl₂) may be dissolved in a first solvent to form a perovskite precursor (S10). The perovskite precursor solution may be used to form the perovskite thin film and then ultimately form the perovskite photoactive layer through subsequent steps, and the perovskite precursor solution may be prepared by dissolving a solute containing a perovskite compound in the first solvent.

The solute is a compound used to form a perovskite compound, and any compound that can form a typical perovskite structure may be used. Specifically, the solute may contain 20 to 25 parts by weight of methylammonium iodide (MAI) and 60 to 65 parts by weight of lead iodide (Pbl₂) with respect to 14 parts by weight of phenethylammonium iodide (PEAI).

If the mixing ratio of the phenethylammonium iodide (PEAI), methylammonium iodide (MAI), and lead iodide (Pbl₂) in the solute is beyond the above-mentioned range, two-dimensional perovskites may not be formed.

The first solvent may be used to dissolve or disperse the solute, which is the perovskite compound. Specifically, the first solvent may comprise at least one selected from the group consisting of dimethylformamide (DMF) and dimethylsulfoxide (DMSO). Depending on the embodiment, additional solvents such as N-methyl-2-pyrrolidone (NMP), 2-methoxyethanol, etc. may be further used to dissolve the perovskite compound.

Subsequently, the perovskite precursor solution may be applied to the substrate to form a perovskite precursor thin film (S20).

The substrate may be used to form the perovskite precursor thin film. The substrate may be any inorganic or organic substrate commonly used in forming perovskite precursor thin films. For example, the substrate may be an inorganic substrate such as sapphire, Si, SiO₂, GaN, AlN, GaP, InP, SiC, glass, graphite, or graphene, or an organic substrate such as polyimide (PI), polyethersulfone (PES), polyacrylate (PAR), polyethylene naphthalate (PEN), polyarylate, or polycarbonate (PC), but not limited thereto.

In one embodiment, the substrate may be heated to a temperature of 100 to 110° C. before applying the perovskite precursor solution.

The perovskite precursor solution may be applied to the substrate by a conventional method used for a thin film formation process using a solution. Specifically, the perovskite precursor solution may be applied to the substrate by spin coating, dip coating, or spray coating. Preferably, in the step of forming the perovskite precursor thin film, the perovskite precursor solution may be applied to the substrate by spin coating. During the spin coating process, the spin coating may be carried out at a rotation speed of 3,000 to 7,000 rpm for 10 to 60 seconds.

Subsequently, the perovskite precursor thin film may be subjected to vacuum treatment, followed by thermal annealing to form a two-dimensional perovskite photoactive layer (S30). Specifically, through the vacuum treatment and thermal annealing, the perovskite precursor thin film may develop a crystal structure with a certain orientation, resulting in a two-dimensional perovskite photoactive layer with a uniform surface.

Specifically, in the step of forming the perovskite photoactive layer, the perovskite precursor thin film may be subjected to vacuum treatment at −1 to −3 bar for 8 to 10 minutes. If the perovskite precursor thin film is subjected to vacuum treatment at a pressure beyond the above-mentioned range, the resulting perovskite photoactive layer may degrade, leading to a higher occurrence of surface defects. Moreover, if the perovskite precursor thin film is subjected to vacuum treatment for a period of time beyond the above-mentioned range, it may affect the crystallinity, potentially reducing the energy efficiency and photostability of the device comprising the same.

After performing the vacuum treatment, the resulting perovskite precursor thin film may be thermally annealed at 100 to 110° C. for 5 to 15 minutes.

If the vacuum-treated perovskite precursor thin film is thermally annealed at a temperature of less than 100° C., it may affect the crystallinity, potentially leading to a decrease in the efficiency of the device comprising the same. Whereas, if the vacuum-treated perovskite precursor thin film is thermally annealed at a temperature exceeding 110° C., a portion of the resulting perovskite photoactive layer may degrade, resulting in an uneven surface structure.

If the vacuum-treated perovskite precursor thin film is thermally annealed for less than 5 minutes, the thermal annealing may not be sufficient, which may affect the crystallinity, and the solvent constituting the perovskite precursor thin film may not be effectively removed. Furthermore, if the vacuum-treated perovskite precursor thin film is thermally annealed for a period of time exceeding 15 minutes, the resulting perovskite photoactive layer may be delaminated, making it difficult to obtain the desired two-dimensional perovskite photoactive layer.

Next, the organic monomolecular compound represented by the above Formula 1 may be dissolved in a second solvent to form an organic monomolecular compound solution (S40). The organic monomolecular compound solution may be used to form a passivation layer consisting of the organic monomolecular compound on the perovskite photoactive layer and may be used to dissolve or disperse the organic monomolecular compound in the second solvent.

In one embodiment, the second solvent may be a polar protic solvent such as common alcohols. Specifically, examples of the alcohols may include methyl alcohol, ethyl alcohol, 1-butyl alcohol, isopropyl alcohol, 1-pentyl alcohol, 1-hexyl alcohol, or benzyl alcohol. Preferably, the second solvent may be isopropyl alcohol (IPA). The isopropyl alcohol (IPA) can effectively dissolve the organic monomolecular compound and can be easily evaporated. Therefore, after being introduced into the top of the perovskite photoactive layer, it does not leave any stains, thus not affecting the surface defects in the perovskite photoactive layer.

In the step of forming the organic monomolecular compound solution, 0.05 to 0.10 parts by weight of N-tert-butyl-α-phenylnitrone (PBN) may be mixed with 100 parts by weight of the second solvent.

If the N-tert-butyl-α-phenylnitrone (PBN) is mixed with the second solvent in amounts less than 0.05 parts by weight for every 100 parts by weight of the second solvent, the N-tert-butyl-α-phenylnitrone (PBN) may not be sufficiently dispersed or dissolved, which may subsequently affect the rate of forming the passivation layer and the degree of passivation when introduced into the top of the perovskite photoactive layer in a later step.

In addition, if the N-tert-butyl-α-phenylnitrone (PBN) is mixed with the second solvent in amounts exceeding 0.10 parts by weight for every 100 parts by weight of the second solvent, it may result in excessive solvent usage, leading to an increase in manufacturing costs.

Subsequently, the organic monomolecular compound solution may be applied onto the top of the perovskite photoactive layer to form a passivation layer (S50). That is, the surface of the perovskite photoactive layer may be passivated by a passivation layer consisting of the organic monomolecular compound formed by applying the organic monomolecular compound solution onto the top of the perovskite photoactive layer.

The organic monomolecular compound solution may be applied onto the top of the perovskite photoactive layer by a conventional method used for a thin film formation process using a solution. Preferably, the organic monomolecular compound solution may be applied onto the top of the perovskite photoactive layer by spin coating. In one embodiment, the spin coating may be carried out at a rotation speed of 3,000 to 7,000 rpm for 10 to 60 seconds.

As described above, according to the method of preparing a perovskite photoactive composite layer of the present inventive concept, it is possible to form a passivation layer by applying the organic monomolecular compound solution onto the top of the perovskite photoactive layer through a simple solution process, thereby effectively passivating the surface of the perovskite photoactive layer. Moreover, it is possible to induce the crystal growth in the vertical direction during the recrystallization of the two-dimensional perovskites, which will be described in detail below with reference to the Examples and the accompanying drawings.

Perovskite Solar Cell with Perovskite Photoactive Composite Layer

Still another aspect of the present inventive concept provides a perovskite solar cell comprising a perovskite photoactive composite layer.

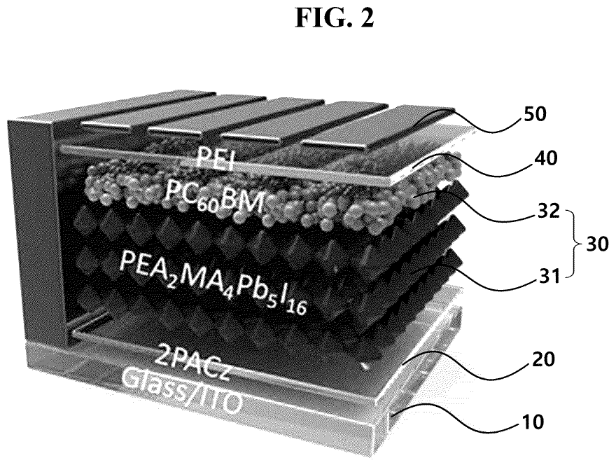

FIG. 2 is a schematic diagram illustrating the structure of a perovskite solar cell according to an embodiment of the present inventive concept.

Referring to FIG. 2, the perovskite solar cell may comprise: a first electrode 10; a hole transport layer 20 formed on the first electrode 10; a perovskite photoactive composite layer 30 formed on the hole transport layer 20 and comprising a two-dimensional perovskite photoactive layer 31 and a passivation layer 32 which is in physical contact with the perovskite photoactive layer 31 and consists of an organic monomolecular compound represented by the following Formula 1; a charge transport layer 40 formed on the perovskite photoactive composite layer 30; and a second electrode 50 formed on the charge transport layer 40.

First, the first electrode 10 may be prepared. The first electrode 10 may be an anode and may contain an electrode material commonly used as an anode for perovskite solar cells. Specifically, for example, the first electrode 10 may comprise a conductive metal oxide, metal, metal alloy, or carbon material. The conductive metal oxide may be an indium tin oxide (ITO), a fluorine tin oxide (FTO), an antimony tin oxide (ATO), a fluorine-doped tin oxide (FTO), SnO₂, ZnO, or a combination thereof. Preferably, the conductive metal oxide used for the first electrode 10 may be an indium tin oxide (ITO).

Depending on the embodiment, as shown in FIG. 2, the material constituting the first electrode 10 may be formed on a typical base substrate. In one embodiment, the base substrate may be a glass substrate.

The first electrode 10 may be formed by physical vapor deposition, chemical vapor deposition, sputtering, pulse laser deposition, evaporation, electron beam evaporation, atomic layer deposition, or molecular beam epitaxy deposition.

Subsequently, the hole transport layer 20 may be formed on the first electrode 10. The hole transport layer 20 may be a p-type semiconductor and contain a hole transport material, and any hole transport material for solar cells can be used. The hole transport material may comprise at least one selected from the group consisting of porphyrin derivatives such as 2-(9H-Carbazol-9-yl)ethyl] phosphonic acid (2PACz), N,N-dicarbazolyl-3,5-benzene (mCP), poly (3,4-ethylenedioxythiophene): polystyrenesulfonate (PEDOT: PSS), N,N′-diphenylbenzidine (NPD), N,N′-diphenyl-N,N′-di (3-methylphenyl)-4,4′-diaminobiphenyl (TPD), N,N′-diphenyl-N,N′-dinaphthyl-4,4′-diaminobiphenyl, N,N,N′N′-tetra-p-tolyl-4,4′-diaminobiphenyl, N,N,N′N′-tetraphenyl-4,4′-diaminobiphenyl, copper (II) 1,10,15,20-tetraphenyl-21H,23H-porphyrin, etc.; triarylamine derivatives such as 1,1-Bis [4-[N,N′-Di (p-tolyl)amino]phenyl] cyclohexane (TAPC), N,N, N-tris (p-tolyl)amine, and 4,4′,4″-tris [N-(3-methylphenyl)-N-phenylamino] triphenylamine; carbazole derivatives such as N-phenylcarbazole and polyvinylcarbazole; phthalocyanine derivatives such as metal-free phthalocyanine and copper phthalocyanine; starburst amine derivatives; enamine-stilbene derivatives; derivatives of aromatic tertiary amines and stilbene amine compounds; and polysilane.

Preferably, the hole transport layer 20 may comprise 2-(9H-Carbazol-9-yl)ethyl] phosphonic acid (2PACz) represented by the following Formula).

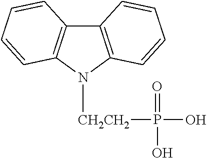

In one embodiment, the hole transport layer 20 may be formed by spin coating, dip coating, thermal evaporation, or spray deposition.

Subsequently, the perovskite photoactive composite layer 30 may be formed on the hole transport layer 20. As described above, the perovskite photoactive composite layer 30 may comprise a two-dimensional perovskite photoactive layer 31 and a passivation layer 32 which is in physical contact with the perovskite photoactive layer and consists of an organic monomolecular compound represented by the above Formula 1. Accordingly, the perovskite photoactive composite layer 30 may refer to the description of the perovskite photoactive composite layer described above.

The perovskite photoactive composite layer 30 may comprise a two-dimensional perovskite photoactive layer 31 and a passivation layer 32 which is in physical contact with the perovskite photoactive layer and consists of an organic monomolecular compound. The perovskite photoactive layer may be grown by recrystallization in the vertical direction by the passivation layer consisting of the organic monomolecular compound, which facilitates the transfer of charges within the cell, thereby improving efficiency. Furthermore, the passivation layer allows for the healing of surface defects, thereby providing a high-quality and uniform perovskite photoactive composite layer.

The perovskite photoactive layer 30 may consist of a perovskite material suitable for solar cells. Specifically, the perovskite may be (PEA)₂(MA)₄Pb₅l₁₆ (i.e., a n=5 PEA-based halide perovskite) comprising phenethylammonium iodide (PEAI), methylammonium iodide (MAI), lead iodide (Pbl₂) and lead chloride (PbCl₂).

The perovskite photoactive composite layer 30 may be placed between the hole transport layer 20 and the charge transport layer 40 to function as an electrolyte layer.

The organic monomolecular compound constituting the passivation layer 32 may contain zwitterions, and the zwitterions may be ionically bound to halogen atoms of the perovskite photoactive layer to inhibit the release of halogen atoms, which will be described in detail below with reference to the following Examples and Experimental Examples.

Next, the charge transport layer 40 may be formed on the perovskite photoactive composite layer 30. The charge transport layer 40 may be an n-type semiconductor and contain a charge transport material typically used for solar cells. Specifically, for example, the charge transport layer 40 may comprise at least one selected from the group consisting of [6,6]-phenyl-C₆₁-butyric acid methyl ester (PCBM), poly (ethyleneimine) (PEI), SnO₂, ZnO, TiO₂, C₆₀ derivative, diphenylphosphine oxide-4-(triphenylsilyl)phenyl (TSPO1), 1,3,5-tris(N-phenylbenzimidazol-2-yl)benzene (TPBi), tris(8-quinolinolate)aluminum (Alq3), 2,5-diaryl silol derivative (PyPySPyPy), perfluorinated compound (PF-6P), octa-substituted cyclooctatetraene (COTs), 4,7-diphenyl-1,10-phenanthroline (Bphen).

Next, the second electrode 50 may be formed on the charge transport layer 40. The second electrode 50 is a cathode where electrons are injected and may comprise a material commonly used as the cathode in solar cells. Specifically, for example, the second electrode 50 may be made of a conductive material such as metal. Examples of the metals may include copper (Cu), aluminum (AI), magnesium (Mg), calcium (Ca), sodium (Na), potassium (K), indium (Id), yttrium (Y), lithium (Li), silver (Ag), lead (Pb), and cesium (Cs) or alloys thereof, but not limited thereto.

In terms of the photostability of the perovskite solar cell of the present inventive concept, when the perovskite solar cell is exposed to light and measured by the maximum power point tracking method under a nitrogen atmosphere, the solar cell may retain its performance at 88% of the initial efficiency even after 1,000 hours, which will be described in detail below with reference to the following Examples and Experimental Examples.

Hereinafter, preferred Examples and Experimental Examples are presented to facilitate the understanding of the present inventive concept. However, the following Examples and Experimental Examples are provided merely for the purpose of facilitating the understanding of the present inventive concept, and the present inventive concept is not limited to the following Examples.

### Example 1: Preparation of Perovskite Photoactive Composite Layers

### Preparation Example 1-1. Preparation of Two-Dimensional Perovskite Photoactive Layer

A perovskite precursor solution was prepared by dissolving a solute containing 0.4 M PEAI (99.64 mg)+0.9 M MAI (143.07 mg)+0.95 M Pbl₂ (437.96 mg)+0.05 M PbCl₂ (13.91 mg) in a solvent comprising 900 μL DMF+100 μL DMSO. The prepared perovskite precursor solution was applied to an ITO substrate heated to 100° C., and then a perovskite thin film was formed by a spin coating process at 5000 rpm for 30 seconds. The resulting perovskite thin film was transferred into a low vacuum chamber (−1 bar) for vacuum treatment. Then, the resulting perovskite thin film was thermally annealed at 100° C. for 5 minutes to prepare a (PEA)₂(MA)₄Pb₅l₁₆ film.

### Example 1-2: Preparation of Passivation Layer Consisting of the Organic Monomolecular Compound

N-tert-butyl-α-phenylnitrone (PBN) was prepared as an organic monomolecular compound (purchased by SIGMA Aldrich). An organic monomolecular compound solution was prepared by dissolving 0.5 mM (0.88 mg) of PBN in 1 mL of isopropyl alcohol (IPA) solvent. The prepared organic monomolecular compound solution was applied onto the top of the two-dimensional perovskite photoactive layer prepared in Example 1-1, and then a passivation layer was formed by a spin coating process at 5000 rpm for 20 seconds to passivate the surface of the perovskite photoactive layer.

### Example 2: Preparation of perovskite solar cell comprising perovskite photoactive composite layers of Example 1

As shown in FIG. 2, for the first electrode 10, an indium tin oxide (ITO) was formed on a glass substrate.

For the hole transport layer 20, 2-(9H-Carbazol-9-yl)ethyl] phosphonic acid (2PACz) was formed on the first electrode 10.

For the perovskite photoactive composite layer 30, a two-dimensional perovskite photoactive layer 31 was formed on the hole transport layer 20 and a passivation layer 32 was formed on the perovskite photoactive layer 31 to be in physical contact therewith in the same manner as Example 1-1 and Example 1-2.

For the charge transport layer 40, [6,6]-phenyl-C₆₁-butyric acid methyl ester (PC₆₀BM) and polyethyleneimine (PEI) were formed on the perovskite photoactive composite layer 30.

For the second electrode 50, a metal electrode (copper (Cu)) was formed on the charge transport layer 40 to prepare a perovskite solar cell.

### Comparative Example 1: Preparation of perovskite photoactive layer

A two-dimensional perovskite photoactive layer was prepared in the same manner as Example 1-1, without carrying out Example 1-2.

### Comparative Example 2: Preparation of perovskite solar cell comprising perovskite photoactive layer

A perovskite solar cell was prepared in the same manner as Example 2, except that the perovskite photoactive layer prepared in Comparative Example 1 was used.

### Experimental Example 1: Time-of-Flight Secondary-Ion Mass Spectrometry of Perovskite Photoactive Composite Layer

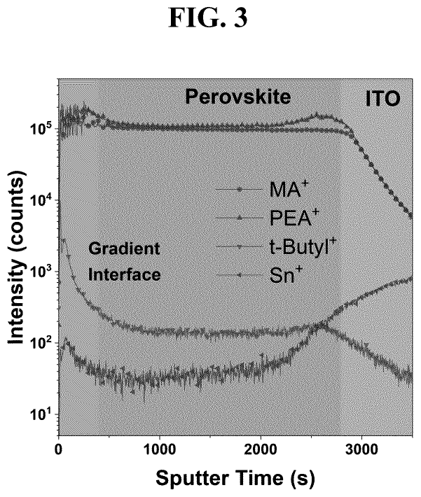

The time-of-flight secondary-ion mass spectra of the perovskite photoactive composite layer comprising the two-dimensional perovskite photoactive layer and the passivation layer consisting of the organic monomolecular compound prepared in Example 1 were analyzed, and the analysis results are shown in FIG. 3.

### (1) Measurement Method

An Ar cluster ion beam with an energy of 5 keV was irradiated onto the perovskite photoactive composite layer film, which was then analyzed while sputtering the film. The ionized components of the sputtered materials were detected by a detector.

### (2) Measurement Results

In FIG. 3, t-butyl+ shown in red represents the organic monomolecular compound, MA and PEA shown in blue and green represent perovskite composition materials, and Sn shown in purple represents the material constituting an ITO electrode substrate. As a result, the components of the perovskite photoactive composite layer formed in Example 1 can be confirmed.

### Experimental Example 2: Ultraviolet Photoelectron Spectroscopy Measurement of Perovskite Photoactive Composite Layer

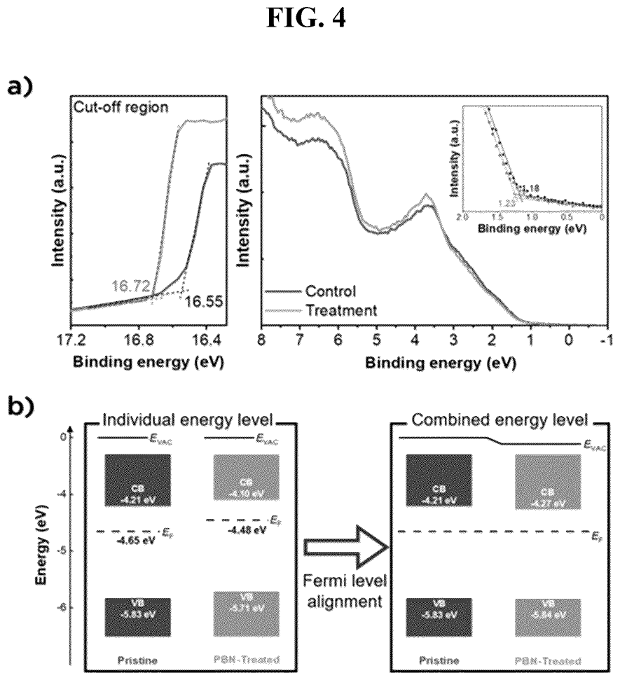

Ultraviolet photoelectron spectroscopy was conducted on the typical two-dimensional perovskite photoactive layer of Comparative Example 1 and the perovskite photoactive composite layer comprising the two-dimensional perovskite photoactive layer and the passivation layer consisting of the organic monomolecular compound prepared in Example 1. The graphs illustrating the ultraviolet photoelectron emission spectra and the corresponding images representing their energy band structures are shown in FIG. 4.

### (1) Measurement Method

When a He (I) beam with an energy of 21.22 eV was irradiated onto the perovskite photoactive composite layer film, photons were emitted from the film surface.

These photons were then detected by a detector to determine the Fermi energy level and the energy level at the valence band of the material constituting the perovskite photoactive composite layer.

### (2) Measurement Results

Referring to FIG. 4, it can be seen that, unlike the perovskite materials constituting the typical two-dimensional perovskite photoactive layer (Control) of Comparative Example 1, the perovskite materials constituting the perovskite photoactive composite layer (Treatment) with the passivation layer treated with the organic monomolecular compound of Example 1 undergoes a change in energy level. As a result, it is inferred that applying the perovskite photoactive composite layer of the present inventive concept to a device can induce smooth charge transfer within the perovskite photoactive composite layer based on the observed change in energy level.

### Experimental Example 3: Grazing-Incidence Wide-Angle X-Ray Scattering Analysis of Perovskite Photoactive Composite Layer and Analysis of Crystal Intensity in Vertical Plane and Horizontal Plane and at Each Angle

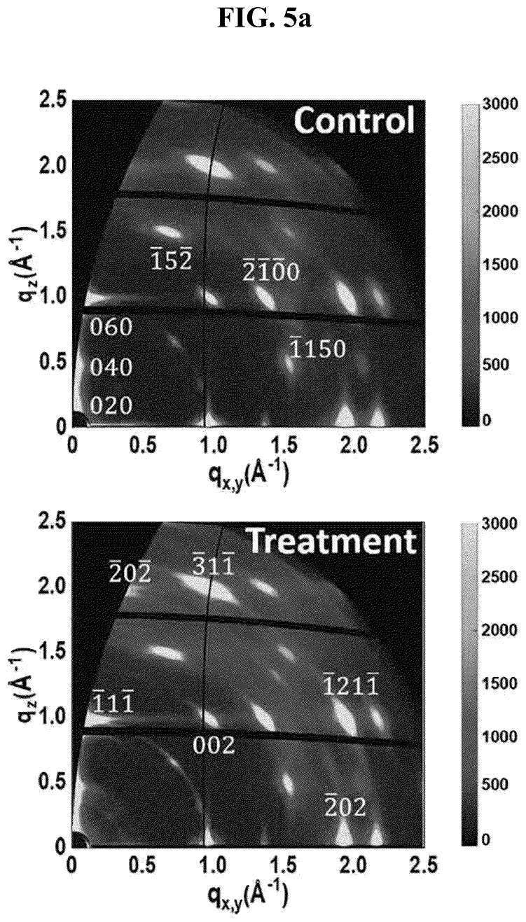

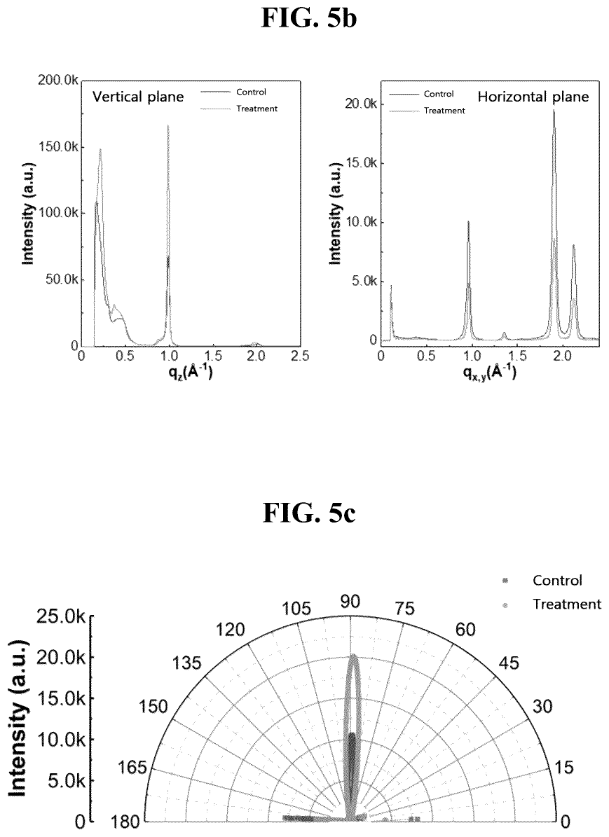

Grazing-incidence wide-angle X-ray scattering analysis and crystal intensity analysis in the vertical plane and horizontal plane and at each angle were conducted on the typical two-dimensional perovskite photoactive layer of Comparative Example 1 and the perovskite photoactive composite layer comprising the two-dimensional perovskite photoactive layer and the passivation layer consisting of the organic monomolecular compound prepared in Example 1. The measurement results are shown in FIG. 5a and FIG. 5b and FIG. 5c.

### (1) Measurement Method

After irradiating 9.8 keV X-rays generated by the accelerator onto the perovskite photoactive composite layer film, the diffracted X-ray beam was measured by a detector.

### (2) Measurement Results

It can be observed that the vertical crystal orientation of the two-dimensional perovskite photoactive layer prepared in Example 1 of the present inventive concept has increased, while the horizontal orientation has decreased. Moreover, it is evident that the crystallinity of the perovskite photoactive layer of Example 1 has been improved compared to the typical two-dimensional perovskites (Control) of Comparative Example 1.

As described above, according to the present inventive concept, the passivation layer consisting of the organic monomolecular compound formed on the two-dimensional perovskite photoactive layer can effectively induce the vertical recrystallization orientation of perovskites.

### Experimental Example 4: Scanning Electron Microscopy (SEM) Analysis of Perovskite Photoactive Composite Layer

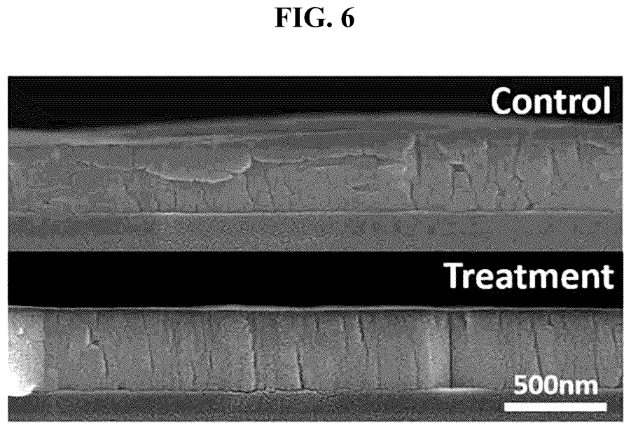

The cross sections of the typical two-dimensional perovskite photoactive layer of Comparative Example 1 and the perovskite photoactive composite layer of Example 1 were analyzed by scanning electron microscopy (SEM). The analysis results are shown in FIG. 6.

Referring to FIG. 6, it can be seen that the typical two-dimensional perovskite photoactive layer (Control) of Comparative Example 1 has been grown by recrystallization in the horizontal direction. In contrast, the cross-section of the perovskite photoactive composite layer (Treatment) prepared in Example 1 of the present inventive concept has been grown by recrystallization in the vertical direction.

As a result, it can be confirmed that the passivation layer of the present inventive concept which consists of an organic monomolecular compound formed on the two-dimensional perovskite photoactive layer has effectively induced the vertical crystal orientation of perovskite.

### Experimental Example 5: Analysis of Defects and Energy Changes in Perovskite Photoactive Composite Layer

### Experimental Example 5-1: Space-Charge Limited Current Measurements

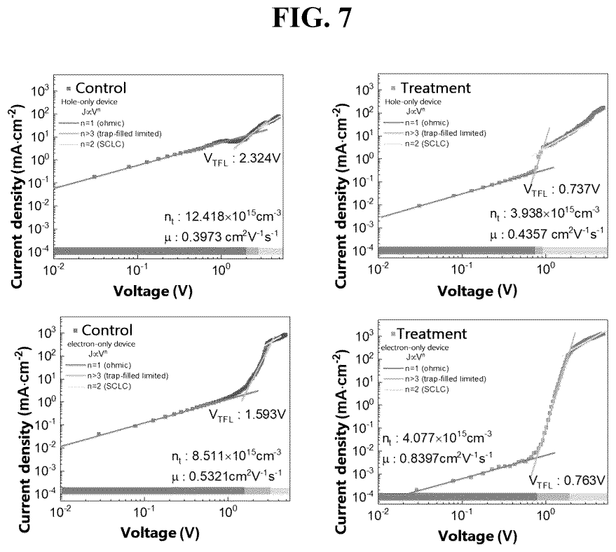

The space-charge limited current of the perovskite photoactive layer of Comparative Example 1 and the perovskite photoactive composite layers of Example 1 were measured. The measured current values were used to calculate the defect concentration and the charge carrier mobility using the following Equations (1) and (2). The measurement and calculation results are shown in FIG. 7.

$${n}_{t} = 2 {ε}_{0} {ε}_{r} {V}_{TFL} / {qL}^{2} \qquad Equation ( 1 )$$

where, nₜ represents the defect concentration, ε₀ represents the vacuum permittivity, εᵣ represents the relative permittivity of perovskite, V_{TFL} represents the trap-filled limit voltage, q represents the basic charge, and L represents the thickness of the film.

$$J = \frac{9}{8} {ε}_{o} {ε}_{r} μ \frac{{V}^{2}}{{L}^{3}} \qquad Equation ( 2 )$$

where μ represents the mobility, J represents the current, and V represents the voltage.

Referring to FIG. 7, it can be seen that, unlike Comparative Example 1, the defect density of the two-dimensional perovskite photoactive layer with the passivation layer consisting of the organic monomolecular compound of Example 1 has decreased. Consequently, it can be inferred that the charge mobility has increased accordingly.

### Experimental Example 5-2: Analysis of Density and Energy Changes Depending on the Density of Trap States

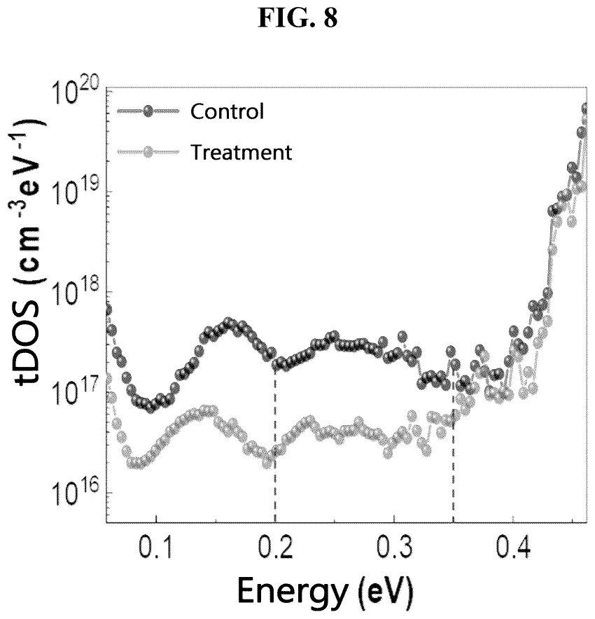

The perovskite photoactive layer of Comparative Example 1 (Control) and the perovskite photoactive composite layers of Example 1 (Treatment) were analyzed by thermal admittance spectroscopy, and then the density of trap states (tDOS)) as a function of energy was calculated using the following Equations (3) and (4). The measurement and calculation results are shown in FIG. 8.

$${N}_{t} ( {E}_{a} ) = - ( \frac{{V}_{bi}}{qW {κ}_{B} T} ) ( \frac{dC}{df} ) f \qquad Equation ( 3 )$$

where V_{bi} represents the built-in-potential, W represents the space-charge region, KB represents the Boltzmann constant, T represents the temperature, f represents the frequency, C represents the capacitance, q represents the basic charge, and Nₜ represents the density of trap states.

Referring to FIG. 8, it can be observed that, compared to Comparative Example 1 the density of trap states of the perovskite photoactive composite layer comprising the passivation layer consisting of the organic monomolecular compound of Example 1 has decreased.

As described above, according to the present inventive concept, the organic monomolecular compound applied to a two-dimensional perovskite photoactive layer can induce the recrystallization growth of perovskite in the vertical direction, resulting in smoother charge mobility, while reducing the density of trap states. Consequently, it is anticipated that the perovskite photoactive composite layer of the present inventive concept applied to a solar cell can improve the energy efficiency of the cell.

### Experimental Example 6: Spectral Analysis of Perovskite Photoactive Composite Layer

### Experimental Example 6-1: Transient Absorption and Photobleaching Measurement for Each Wavelength Region

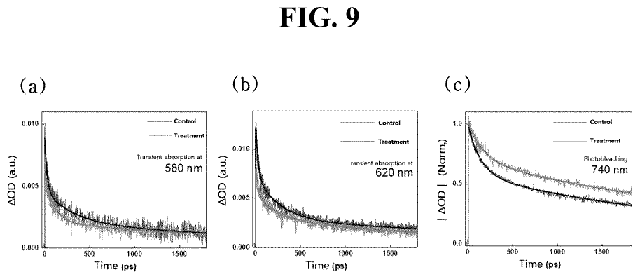

The perovskite photoactive layer of Comparative Example 1 (Control) and the perovskite photoactive composite layers of Example 1 (Treatment) were irradiated with wavelength-specific lasers to measure the transient absorption and photobleaching for each wavelength region. The measurement results are shown in FIG. 9.

Referring to FIG. 9, it can be observed that, compared to the perovskite photoactive layer of Comparative Example 1, the transient absorption rate of the two-dimensional perovskite material constituting the perovskite photoactive composite layers of Example 1 is faster in the short wavelength region, while the rate of photobleaching is slower in the long wavelength region.

### Experimental Example 6-2: Analysis of Photoluminescence and Time-Correlated Single Photon Counting

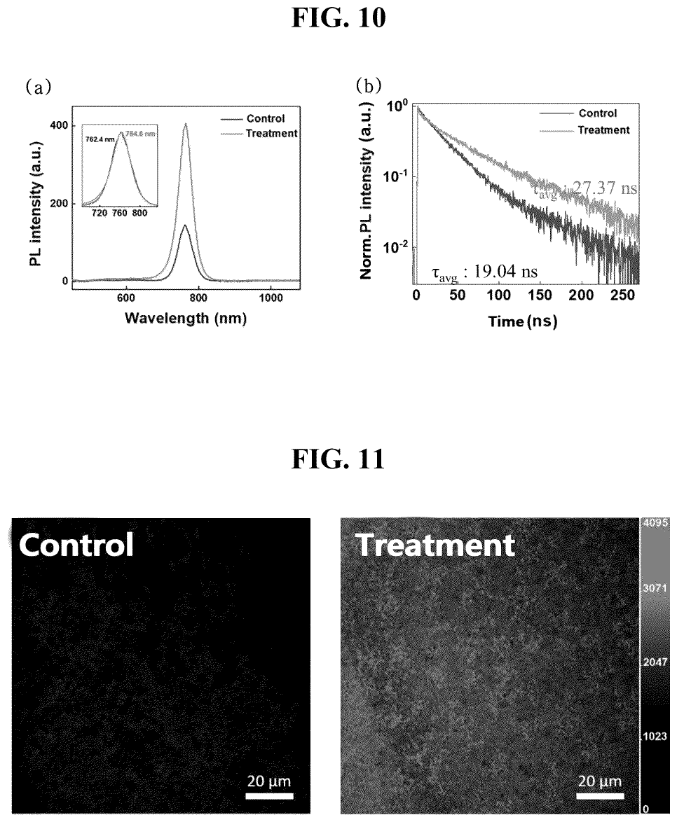

The perovskite photoactive layer of Comparative Example 1 (Control) and the perovskite photoactive composite layers of Example 1 (Treatment) were irradiated with a laser with a wavelength of 375 nm, and the resulting optical properties were observed and analyzed with a fluorescence detector. The analysis results are shown in FIG. 10.

As shown in FIG. 10, the analysis results indicate that, compared to the perovskite photoactive layer of Comparative Example 1, the intensity of photoluminescence of the perovskite photoactive composite layers of Example 1 has been improved, and its lifetime has also increased. This can be attributed to the effect of smooth charge movement within the two-dimensional perovskites where the recrystallization growth occurred in the vertical direction.

### Experimental Example 6-3: Confocal Laser Scanning Microscopy Analysis

The perovskite photoactive layer of Comparative Example 1 (Control) and the perovskite photoactive composite layers of Example 1 (Treatment) were irradiated with a laser with a wavelength of 405 nm, and the resulting optical properties were observed by confocal laser scanning microscopy (CLSM). The analysis results are shown in FIG. 11.

Referring to FIG. 11, it can be observed that, compared to the perovskite photoactive layer of Comparative Example 1, the perovskite photoactive composite layers of Example 1 show an overall increase in optical properties (photoluminescence), rather than in localized areas.

As described above, the perovskite photoactive composite layer of the present inventive concept can improve the optical properties due to the effective charge transfer, leading to improved power conversion efficiency when applied to solar cells.

### Experimental Example 7: Evaluation of Performance and Photostability of Perovskite Solar Cells

### Experimental Example 7-1: Measurement of Current Density and Efficiency Depending on the Voltage of Perovskite Solar Cells

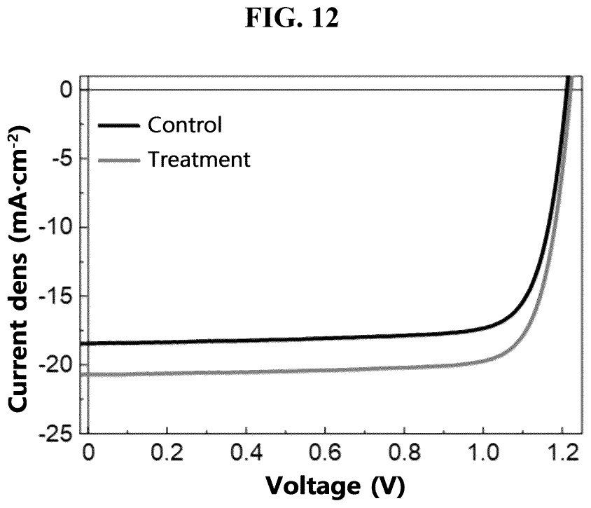

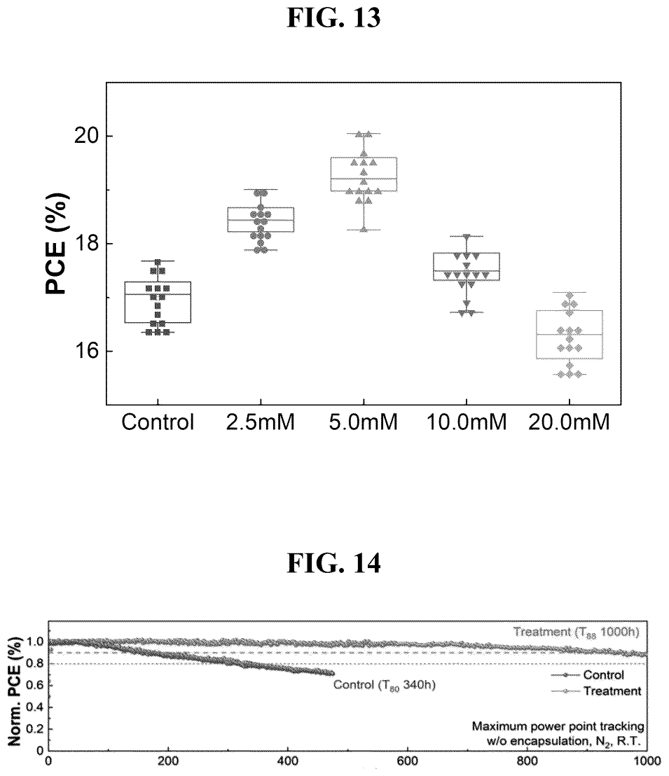

The current density as a function of the voltage of the perovskite solar cell of Comparative Example 2 and the perovskite solar cell of Example 2 was measured, and based on this, the power conversion efficiency (PCE) was analyzed. The analysis results are shown in the following Table 1 and FIGS. 12 and 13.

TABLE 1

| | Open-circuit | Short-circuit | Fill | Efficiency |
|---|---|---|---|---|
| Sample | voltage (V) | current (mA · cm⁻²) | factor | (%) |
| Control | 1.21 | 18.44 | 0.78 | 17.53 |
| Treatment | 1.22 | 20.71 | 0.79 | 20.05 |

Referring to Table 1 and FIGS. 12 and 13, it can be seen that the performance of the perovskite solar cell of Example 2 (Treatment) has been improved compared to the perovskite solar cell of Comparative Example 2 (Control). This can be attributed to the increase in current within the perovskite photoactive layer of the present inventive concept due to the presence of the passivation layer consisting of the organic monomolecular compound.

### Experimental Example 7-2: Analysis of Changes in Efficiency of Perovskite Solar Cells Over Time

The efficiency over time of the perovskite solar cell of Comparative Example 2 (Control) and the perovskite solar cell of Example 2 (Treatment) was measured. The measurement results are shown in FIG. 14.

### (1) Measurement Method

The perovskite solar cells of Comparative Example 2 and Example 2 were exposed to sunlight, and their efficiency over time was measured by the maximum power point tracking method under a nitrogen atmosphere.

### (2) Measurement Results

Referring to FIG. 14, it can be observed that the efficiency of the perovskite solar cell (Control) of Comparative Example 2 gradually decreases over time, and after about 340 hours, the performance of the solar cell has decreased to about 80% of the initial efficiency.

On the contrary, it can be seen that the perovskite solar cell (Treatment) of Example 2 maintains its performance within 88% of the initial efficiency even after 1,000 hours. This indicates that the stability of the perovskite solar cell comprising the perovskite photoactive composite layer of the present inventive concept has been improved.

### Experimental Example 7-3: Measurement of Ultraviolet-Visible Absorption Spectra and Electrostatic Potential Simulation Analysis of Perovskite Photoactive Composite Layer

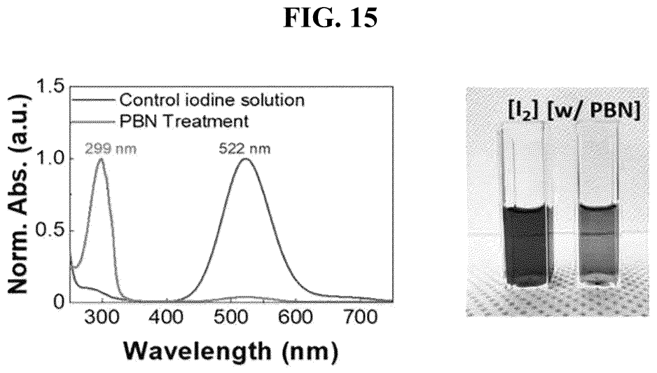

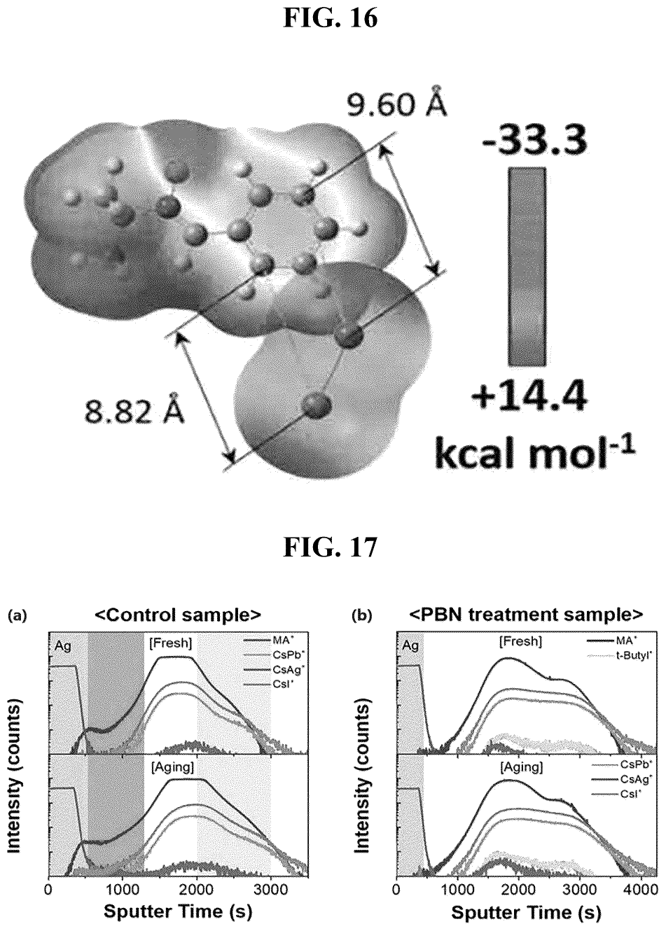

The ultraviolet-visible absorption spectra of a control iodine solution and a solution containing the organic monomolecular compound PBN of Formula 1 were measured, and the electrostatic potential simulation for the organic monomolecular compound of Formula 1 was analyzed. The analysis results are shown in FIGS. 15 and 16.

Referring to FIG. 15, the iodine solution treated with organic monomolecular (PBN) exhibits the highest absorption value at a lower wavelength of 299 nm, unlike the control iodine solution. In FIG. 16, the electrostatic potential simulation analysis indicates that the surface defects of the two-dimensional perovskite photoactive layer have been healed due to the capture effect of the organic monomolecular compound PBN passivated on the two-dimensional perovskite photoactive layer.

### Experimental Example 7-4: Time-of-Flight Secondary-Ion Mass Spectrometry of Perovskite Photoactive Composite Layer

The perovskite solar cells of Comparative Example 2 and Example 2 were subjected to time-of-flight secondary-ion mass spectrometry analysis. The measurement results are shown in FIG. 17.

As shown in FIG. 17, it can be observed that, unlike the perovskite solar cell of Comparative Example 2 (Control), the movement of perovskite components constituting the perovskite photoactive composite layer of the perovskite solar cell (Treatment) of Example 2 has been inhibited. This can be attributed to the fact that the zwitterions of the organic monomolecular compound constituting the perovskite photoactive composite layer of Example 2 are ionically bound to halogen atoms of the perovskite photoactive layer to inhibit the release of halogen atoms.

As described above, the perovskite photoactive composite layer of the present inventive concept and the solar cell comprising the same can improve the quality by passivating the surface defects in the two-dimensional perovskite photoactive layers through the introduction of the functional organic monomolecular compound onto the surface of two-dimensional perovskites, potentially increasing the power conversion efficiency and photostability of the solar cell comprising the same.

It will be readily understood by those skilled in the art will that the foregoing description of the present inventive concept is for illustrative purposes, and the present inventive concept can be easily modified into other specific forms without altering the technical idea or essential features of the present inventive concept. Therefore, the embodiments described above should be understood as illustrative in all respects and not restrictive. For example, each component described as a single type can also be implemented in a distributed manner, and similarly, components described as being distributed can also be implemented in a combined form.

The scope of the present inventive concept is defined by the claims provided below, and all changes and modifications derived from the meaning and scope of the claims and their equivalent concepts should be construed as being included in the present inventive concept.

What is claimed is:

1. A perovskite photoactive composite layer comprising:
a two-dimensional perovskite photoactive layer; and
a passivation layer which is in physical contact with the perovskite photoactive layer and consists of an organic monomolecular compound represented by the following Formula 1: 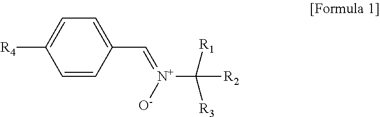
wherein R₁, R₂ and R₃ are each independently hydrogen or C₁-C₃₀ alkyl, and R₄ is hydrogen or an aromatic compound.

2. The perovskite photoactive composite layer of claim 1, wherein in Formula 1, R₁, R₂, and R₅ are each methyl, and R₄ is hydrogen.

3. The perovskite photoactive composite layer of claim 1, wherein the perovskite photoactive layer is grown by recrystallization in the vertical direction.

4. A method of preparing a perovskite photoactive composite layer as defined in claim 1, the method comprising the steps of:
preparing a perovskite precursor solution by dissolving a solute containing phenethylammonium iodide (PEAI), methylammonium iodide (MAI), lead iodide (Pbl₂), and lead chloride (PbCl₂) in a first solvent;
forming a perovskite precursor thin film by applying the perovskite precursor solution to a substrate;
forming a two-dimensional perovskite photoactive layer by subjecting the perovskite precursor thin film to vacuum treatment, followed by thermal annealing;
preparing an organic monomolecular compound solution by dissolving an organic monomolecular compound represented by the above Formula 1 in a second solvent: 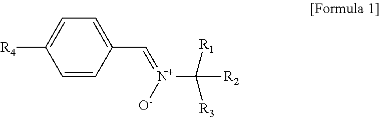
wherein R₁, R₂ and R₃ are each independently hydrogen or C₁-C₃₀ alkyl, and R₄ is hydrogen or an aromatic compound; and
forming a passivation layer by applying the organic monomolecular compound solution onto the top of the perovskite photoactive layer.

5. The method of preparing a perovskite photoactive composite layer of claim 4, wherein the organic monomolecular compound is N-tert-butyl-α-phenylnitrone (PBN).

6. The method of preparing a perovskite photoactive composite layer of claim 4, wherein the solute contains 20 to 25 parts by weight of methylammonium iodide (MAI) and 60 to 65 parts by weight of lead iodide (Pbl₂) with respect to 14 parts by weight of phenethylammonium iodide (PEAI).

7. The method of preparing a perovskite photoactive composite layer of claim 4, wherein the first solvent comprises at least one selected from the group consisting of dimethylformamide (DMF) and dimethylsulfoxide (DMSO).

8. The method of preparing a perovskite photoactive composite layer of claim 4, wherein in the step of forming the perovskite precursor thin film, the perovskite precursor solution is applied to the substrate by spin coating.

9. The method of preparing a perovskite photoactive composite layer of claim 4, wherein in the step of forming the perovskite photoactive layer, the perovskite precursor thin film is subjected to vacuum treatment at −1 to −3 bar for 8 to 10 minutes, followed by thermal annealing at 100 to 110° C. for 5 to 15 minutes.

10. The method of preparing a perovskite photoactive composite layer of claim 4, wherein the second solvent is isopropyl alcohol (IPA).

11. The method of preparing a perovskite photoactive composite layer of claim 4, wherein in the step of forming the organic monomolecular compound solution, 0.05 to 0.10 parts by weight of N-tert-butyl-α-phenylnitrone (PBN) is mixed with 100 parts by weight of the second solvent.

12. A perovskite solar cell comprising:
a first electrode;
a hole transport layer formed on the first electrode;
a perovskite photoactive composite layer formed on the hole transport layer and comprising a two-dimensional perovskite photoactive layer and a passivation layer which is in physical contact with the perovskite photoactive layer and consists of an organic monomolecular compound represented by the following Formula 1: 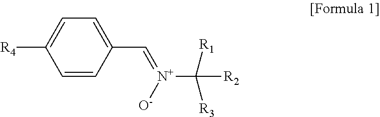
wherein R₁, R₂ and R₃ are each independently hydrogen or C₁-C₃₀ alkyl, and R₄ is hydrogen or an aromatic compound; and
a charge transport layer formed on the perovskite photoactive composite layer; and
a second electrode formed on the charge transport layer.

13. The perovskite solar cell of claim 12, wherein the organic monomolecular compound contains zwitterions, and the zwitterions are ionically bound to halogen atoms of the perovskite photoactive layer to inhibit the release of halogen atoms.

14. The perovskite solar cell of claim 12, wherein in terms of photostability, when the perovskite solar cell is exposed to light and measured by a maximum power point tracking method under a nitrogen atmosphere, the solar cell retains its performance at 88% of the initial efficiency even after 1,000 hours.
